(19) United States
(12) Patent Application Publication
(10) Pub. No.: US 2002/0006469 A1
(43) Pub. Date: Jan. 17, 2002

(54) Method for incorporating additives in an ophthalmic article by means of a supercritical fluid

(76) Inventors: Gilles Baillet, Paris (FR); Jean-Paul Cano, Chennevieres (FR); Jean-Francois Magne, Sarnen (CH)

Correspondence Address: Robert M. O'Keefe, O'KEEFE, EGAN & PETERMAN, Building C, Suite 200, 1101 Capital of Texas Highway South, Austin, TX, 78746, US

(21) Appl. No.: 09/729,648

(22) Filed: Dec. 4, 2000

Related U.S. Application Data
(63) Continuation-in-part of application No. 09/242,384, filed on Feb. 12, 1999, now abandoned.
Application No. 09/242,384 is a 371 of international application No. PCT/FR97/01469, filed on Aug. 8, 1997.

(30) Foreign Application Priority Data
Aug. 14, 1996 (FR) 96/10229

(51) Int. Cl. B05D 5/06; C23C 16/00

(52) U.S. Cl. 427/162; 427/166; 427/248.1

(57) ABSTRACT

The method comprises introducing into a reactor including a transparent polymer substrate containing a free plasticizer and the photochromic additive, supercritical fluid and maintaining this fluid in the reactor for the time necessary for incorporating the photochromic additive into the article, removing the supercritical fluid and recovering the ophthalmic article in which the photochromic additive has been incorporated.

### BACKGROUND OF THE INVENTION

The present invention relates generally relates to a method for incorporating additives in an ophthalmic article made of organic glass by means of a fluid in the supercritical state.

The present invention more particularly relates to a method for incorporating additives, such as stabilizers, antioxidants, antiozonants, UV absorbers, plasticizers, dyes and pigments (photochromic substances and conventional dyes and pigments), in finished or semi-finished ophthalmic articles made of transparent organic polymers by means of a supercritical fluid for example CO₂ in the supercritical state.

There exists a number of conventional methods for incorporating an additive, in particular a photochromic substance, in a substrate made of transparent organic polymers of an ophthalmic article.

A first conventional method consists in incorporating the various additives in the transparent and liquid monomer composition, in pouring the liquid monomer composition in which the additives are incorporated between the two parts of a mold and in then polymerizing the monomers in order to obtain the ophthalmic article comprising a substrate made of organic glass in which the desired additives are found enclosed. This technique exhibits a number of disadvantages. In particular, when the additives are photochromic pigments or UV absorbers, this method requires polymerization by the thermal route, since the presence of the UV absorber and/or of the photochromic pigments does not generally make possible, or only with great difficulty, a photochemical polymerization. Moreover, the incorporation of photochromic compounds in the case of the use of allylic monomers is virtually ruled out, the method requiring the use of a high concentration of initiator, long polymerization time and relatively high polymerization temperatures. When the additive incorporated is a photochromic substance, there is a risk that the long polymerization times and the relatively high polymerization temperatures will cause degradation of the photochromic substance.

Moreover, it is not rules out that degradation of the photochromic substance is generated by reaction of the latter with radicals originating from thermal or photochemical initiators.

Another conventional technique, used to incorporate conventional dyes in an ophthalmic article, consists in immersing the ophthalmic article, composed of a transparent polymer substrate, in an aqueous dispersion of insoluble dye particles and in heating at a temperature of the order of 90° C. for a time sufficient to cause the dye particles to penetrate into the surface of the polymer substrate. This technique also exhibits a number of disadvantages. First of all, the dispersion has a limited lifetime and has to be discarded after a relatively short time, resulting in a significant loss of dye or requiring expensive stages for recovering the dye. This method is not applied to all types of substrates or polymers and requires, for substrates which are the most resistant to dyeing, the use of an aggressive vector agent (for example phenol derivatives), which results in problems of discharges and risks of environmental pollution. Finally, the incorporation of the dye remains superficial, that is to say that the dye does not penetrate very far under the surface of the substrate, which does not make possible a core dyeing of the substrate.

A recently developed technique, more particularly for the introduction of a photochromic substances into ophthalmic articles comprising a transparent polymer substrate, is the so-called “thermal transfer” technique. This thermal transfer method is described, inter alia, in the documents U.S. Pat. Nos. 4,286,957 and 4,880,667. In this technique, a surface of the transparent polymer substrate is coated with a layer of a varnish containing the photochromic substance to be incorporated. The substrate, thus coated, is then treated thermally in order to cause the photochromic substance to migrate into the substrate. This method also exhibits a number of disadvantages. The heating time necessary to cause the photochromic substance to migrate is relatively long, of the order of 5 hours. Only part of the photochromic substance is introduced into the substrate, so that there are not insignificant losses of photochromic substance. Finally, this method only makes possible a low depth of penetration of the photochromic substance into the substrate, of the order of 150 μm at most.

In the case of the incorporation of a photochromic substance, it is desirable to obtain the greatest possible penetration of this substance into the substrate. This is because the deep layers of photochromic substance act as a reservoir. Thus, as the surface layers of photochromic substance lose, under the effect of repeated UV irradiations, their photochromic characteristics, they are replaced by intact underlying layers of photochromic substance, which prolongs the lifetime of the photochromic ophthalmic article.

The document U.S. Pat. No. 4,598,086 describes a method for impregnating a thermoplastic polymer with an impregnation material (namely a fragrance, a disinfecting or rat-killing agent or a pharmaceutical composition) by dissolving the impregnation material in a volatile blowing agent (for example, CO₂ maintained at or near supercritical conditions), causing the thermoplastic polymer to swell by bringing it into contact with the volatile blowing agent in the supercritical state or near supercritical state containing the impregnation material, and by reducing the pressure, so that the volatile blowing agent diffuses from the polymer.

The polymers act solely as support for an active product which must subsequently be released in a controlled way.

The document U.S. Pat. No. 4,820,752 describes a method for infusing an additive into a polymer by dissolving the additive in a gaseous fluid solvent (for example CO₂) which has a boiling point below room temperature and a density of at least 0.01 g/cm³, by bringing the solution of the additive and the fluid solvent into contact with a polymeric material for a time sufficient to enable at least part of the solution to be absorbed into the polymeric material, and by separating the fluid solvent from the polymeric material, leaving the infused additive therein.

Although this document envisages the use of a supercritical fluid, this condition does not appear to be essential for the method described. Moreover, the only example using a fluid in the supercritical state relates to the incorporation of progesterone in a polyurethane substrate.

The document U.S. Pat. No. 5,340,614 describes the impregnation in a polymer substrate of additives which are insoluble in a supercritical fluid which consists in bringing the polymer substrate, the imprenation additive and a liquid vehicle, such as water, into contact simultaneously in the presence of a supercritical fluid.

The document WO 95/20476 describes the treatment of ophthalmic lenses with a fluid in the supercritical state in order to remove incompletely polymerized materials therefrom.

### SUMMARY OF THE INVENTION

It would thus be desirable to have available a method for incorporating photochromic additives in finished and semi-finished ophthalmic articles comprising a transparent polymer substrate containing at least one free plasticizer which can be applied to all types of polymers which can be used for the manufacture of photochromic ophthalmic articles, which makes it possible to adjust at will the depth of penetration of the photochromic additives into the substrate and which in particular makes possible a core penetration of the additives, even into relatively thick substrates. In addition, this method should make possible short treatment times, should not degrade the photochromic properties of the incorporated additive, should not degrade the physical aid optical properties nor the geometry of the polymer substrate of the ophthalmic article, and should not elute the additives already present in the substrate, and in particular the free plasticizer.

By free plasticizer, it is meant a plasticizer that does not have chemical linkages with the polymer network constituting the substrate.

Thus, the method must not harm in particular the geometry of the polymer substrate, that is to say that it must not deform the polymer substrate to a point such that it will be necessary to reshape the ophthalmic article after the incorporation of the additive. In addition, the method must not harm the advantageous properties of the ophthalmic article, such as the resistance to scratching and to abrasion and the impact strength.

In addition, this method must make possible a homogeneous incorporation of the additive within the polymer substrate. The additive introduced must not be subject to a release phenomenon. Finally, the method must not detrimentally affect the resistance to ageing of the ophthalmic article.

According to the invention, a method for incorporating at least one photochromic additive in a finished or semi-finished ophthalmic article comprising a transparent polymer substrate containing at least one free plasticizer which comprises:

introducing a supercritical fluid into a reactor containing the ophthalmic article and the photochromic additive to be incorporated;

maintaining the supercritical fluid in the reactor, in a static state, for a predetermined period of time, in order to obtain the incorporation of the photochromic additive in the polymer substrate of the ophthalmic article to a predetermined depth;

removing the supercritical fluid; and

recovering the ophthalmic article in which the photochromic additive has been incorporated.

A specific implementation of the method according to the invention relates to a method for the photochromization of a finished or semi-finished ophthalmic article comprising a transparent polymer substrate which comprises:

A. A first stage comprising:

the insertion into a reactor of a transparent polymer substrate and of a plasticizer for the substrate,

the introduction into the reactor of a supercritical fluid,

the maintenance of the supercritical fluid in the reactor, in a static state, for a predetermined period of time, in order to obtain the incorporation of the plasticizer in the polymer substrate, and

the removal of the supercritical fluid; and

B. A second stage comprising:

the insertion into the reactor containing the plasticized polymer substrate of one or more photochromic compounds;

the introduction of a supercritical fluid,

the maintenance of the supercritical fluid in the reactor, in a static state, for a predetermined period of time, in order to obtain the incorporation of the photochromic compound or compounds in the plasticized polymer substrate of the ophthalmic article to a predetermined depth,

the removal of the supercritical fluid, and

the recovery of the ophthalmic article in which the photochromic compound or compounds are incorporated.

### BRIEF DESCRIPTION OF THE DRAWINGS

FIG. 1 shows a representative device that may be used in the practice of this invention.

FIG. 2 shows a representative reactor that may be used in the practice of this invention;

FIG. 3 and FIG. 4 show graphs of the data from examples 1-3.

### DETAILED DESCRIPTION OF THE INVENTION

Materials are generally known in three states solid, liquid and gaseous. Materials change from one to another of these states when the temperature and/or the pressure is/are varied. Now, there exists a point beyond which it is possible to change from the liquid state to the gaseous or vapor state without boiling or, conversely, without condensing, thus without changing: this point is known as the critical point.

A fluid in a state characterized either by a pressure and a temperature which are respectively higher than the critical pressure and the critical temperature, in the case of a pure body, or by a representative point (pressure, temperature) situated beyond the boundary of the critical points represented on a diagram (pressure, temperature), in the case of a mixture, is said to be in the supercritical state.

Carbon dioxide proves to be a particularly advantageous fluid for being used as fluid in the supercritical state, because of its critical parameters (t_{c}=31° C., P_{c}=7.3 MPa), its absence of toxicity, its non-polluting nature and its low costs.

The use of CO₂ in the supercritical state as fluid in the supercritical state is thus recommended in the method according to the invention. The ophthalmic articles which can be treated by the method of the invention are finished or semi-finished articles comprising a transparent polymer substrate.

The finished ophthalmic articles are ophthalmic articles obtained in their definitive shape, generally by pouring polymerizable compositions between two molds exhibiting required surface geometries and then polymerizing. An article is then obtained, the two faces of which are in their final state.

It is often the case that semi-finished articles are manufactured which comprise, after molding, a single face with its final geometry, it being possible for the second face then to be surface-finished as required.

The ophthalmic articles according to the invention comprise, for example, spectacle lenses, sun or corrective lenses, hard of soft contact lenses and hydrogel contact lenses in the dry state.

The ophthalmic articles can also, before the treatment by the method of the invention, contain layers of abrasion-resistant varnish and layers for increasing the impact strength on one of the surface of the transparent polymer substrate.

The polymers of the transparent substrate of the ophthalmic articles which can be used in the method of the invention are all transparent polymers, copolymers and mixtures of the latter which are suitable for the formation of ophthalmic articles.

Mention may be made, among the polymers and copolymers which can be used in the present invention, of allylic polymers, polyol (allyl carbonate) polymers, polyacrylates, poly(alkyl acrylate)s, such as poly(methylmethacrylate)s or such as poly(ethoxy)biphenol A di(meth)acrylates, polyurethanes, polythiourethanes and polycarbonates.

The particularly recommended polymers and copolymers are polycarbonates, such as poly(4,4′-dioxyphenyl-2,2-propane carbonate), poly(ethoxy)bisphenol A dimethacrylate, polyethylene glycol dimethacrylate (PEG dimethacrylate), poly(methyl methacrylate) or poly(allyl carbonate)s, such as diethylene glycol bis(allyl carbonate) and its copolymers.

The polymers and copolymers used for the manufacture of ophthalmic articles are well known and are described, inter alia, in the documents WO 95/10790 and EP-A1-0.653.428.

Besides photochromic substances and plasticizers, the additives which can be incorporated in the polymer substrate of the ophthalmic articles by means of the method according to the invention comprise all additives generally used in polymer substrates of ophthalmic articles and in particular UV absorbers, infrared absorbers, materials for laser screens, stabilizers, antioxidants, conventional dyes and pigments, anti-odor agents, perfumes and mixtures thereof.

The additives which are particularly recommended with the process of the present invention are dyes and pigments and very especially photochromic substances.

Mention may be made, among the UV absorbers which can be used in the present invention, of benzophenones, dihydroxybenzophenones or benzotriazoles. Use may be made, among the stabilizing agents, of sterically-hindered amines.

Mention may be made, among the materials for laser screens, of porphyrin complexes, phthalocyanine derivatives and their mixtures. Such materials are described in the document U.S. Pat. No. 4,657,345.

Mention may be made, among the antioxidants which can be used in the present invention, of phenolic antioxidants, such as monophenols, bisphenols and thiobisphenols, phosphites, such as 4,6-di-tert-butylphenyl phosphite and triphenyl phosphite, or phosphines, such as tiphenylphosphine.

Mention may be made, among the plasticizers which can be used in the present invention, of linear or branched phthalates, such as the phthalates of C₆-C₁₂ alcohols, in particular dioctyl phthalate (DOP), and isophthalates, such as diisodecyl phthalate (DIDP), diisononyl phthalate (DINP) and diisooctyl phthalate (DIOP), as well as benzyl butyl phthalate (BBP) and diisoundecyl phthalate (DIUP), or C₁₈-C₃₀ fatty acid esters, such as adipates, sebacates and azelates.

A preferred class of plasticizers is poly(ethylene glycol)dibenzoates.

Use may be made, among the conventional dyes and pigments, of all dyes and pigments which are conventional in coloring ophthalmic articles, such as, in particular, azo and anthraquinone pigments. Use is preferably made of lipophilic pigments.

Dyes which are particularly useful in the method of the present invention are photochromic substances. These photochromic substances are well known in the art and are substances which, when they are irradiated by a light beam of appropriate wavelengths, change color and return to their original color as soon as the irradiation ceases. Mention may be made, among the photochromic substances which can be used, of benzopyran (chromene) derivatives, in particular naphthopyrans and preferentially diaryl[2H]naphthopyrans, and spirooxazine derivatives. Chromene derivatives are well known in the art and are described, inter alia, in U.S. Pat. No. 3,567,605, International Applications N°90/07507 and N°91/00861 and European Patent Applications EP-0.246.114 and EP-0.401.958.

Spirooxazine derivatives are also well known and are described, inter alia, in numerous patents and patent applications, such as U.S. Pat. Nos. 5,139,707 and 5,114,621 (R. Guglielmetti and P. Tardieu) and European Patent Application EP-0.245.020.

Very clearly, the additives incorporated in the ophthalmic articles by the method of the present invention must not harm the optical properties of the articles obtained.

As indicated above, an important characteristic of the method of the invention is that the additive is brought into contact with the ophthalmic articles in a reactor in the static state in the presence of a fluid in the supercritical state.

Use may be made of any fluid in the supercritical state which is inert with respect to materials constituting the polymer substrate of the ophthalmic article and additive or additives to be introduced. Mention may be made, among the fluids which can be used according to the invention, of CO₂, NO₂, ethylene, ethane and chlorotrifluoromethane.

As indicated above, a particularly recommended fluid is carbon dioxide (CO₂) because it is nontoxic and inexpensive and it can be easily recycled.

The temperature and pressure conditions of the fluid in the supercritical state will very clearly depend on the critical point of the fluid and on the nature of the polymers of the substrate and of the additives to be incorporated. However, it is recommended that the temperature of the fluid in the supercritical state should be lower by 30° C. or more, preferably lower by 50° C., than the glass transition temperature (Tg), under normal conditions, of the polymer polymers of the substrate of the ophthalmic article treated.

The duration of the treatment will very clearly depend on the temperature and pressure conditions of the fluid in the supercritical state, on the nature of the polymer substrate and of the additive to be incorporated, and on the amount and on the depth desired for the incorporation of the additive. In general, it has been found that a duration of 1 to 30 minutes, preferably of 5 to 20 minutes and better still of the order of 10 to 15 minutes was sufficient to obtain the desired incorporation.

Once the incorporation of the additive has been completed, the fluid in the supercritical state absorbed by the substrate is removed. This removal is carried out easily by bringing the substrate back to atmospheric pressure, thus causing expansion of the gas.

The process according to the invention has many advantages. It does not use a solvent and consequently risks of pollution are avoided and the cost related to the possible removal and the possible reprocessing of solvents are eliminated. It makes possible efficient use of the amount of additives because they can be employed until the amount of additives initially introduced into the reactor has been completely exhausted, and consequently prevents additives from being lost and wasted. This economic aspect of the method according to the invention is particularly advantageous for the incorporation of relatively expensive additives, such as photochromic substances. In addition, the method according to the invention makes it possible to adjust the amount and the depth of incorporation of the additive into the polymer substrate and, in particular, makes it possible to obtain a core incorporation, even in significantly thick substrates. Thus, it is possible to carry out incorporations of additives, in particular of photochromic substances and dyes, to depths of 10 mm, preferably of 1 to 2 mm.

By way of comparison, the thermal transfer process only makes it possible to incorporate photochromic substances to depths of the order of 150 μm.

The method according to the invention also makes it possible to incorporate additives, in particular photochromic substances and dyes, in polymer substrates regarded until now as difficult or even impossible to color, such as polycarbonate substrates or substrates coated with an abrasion-resistant and/or impact-resistant layer.

The following examples illustrate the present invention without, however, limiting it.

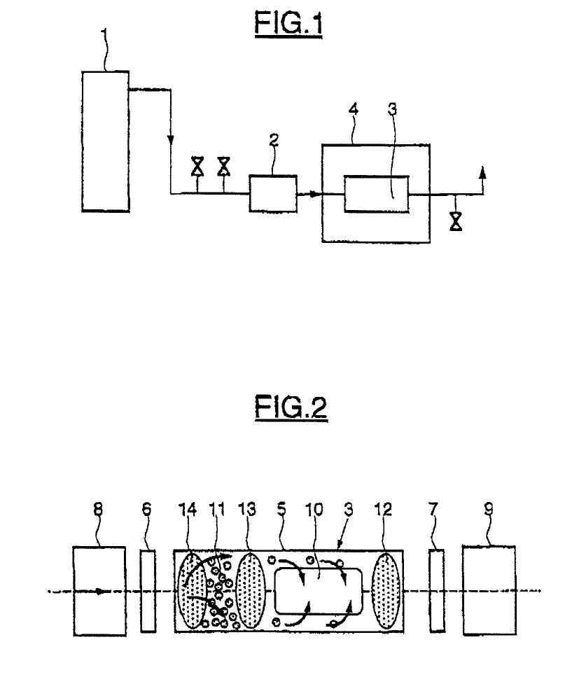

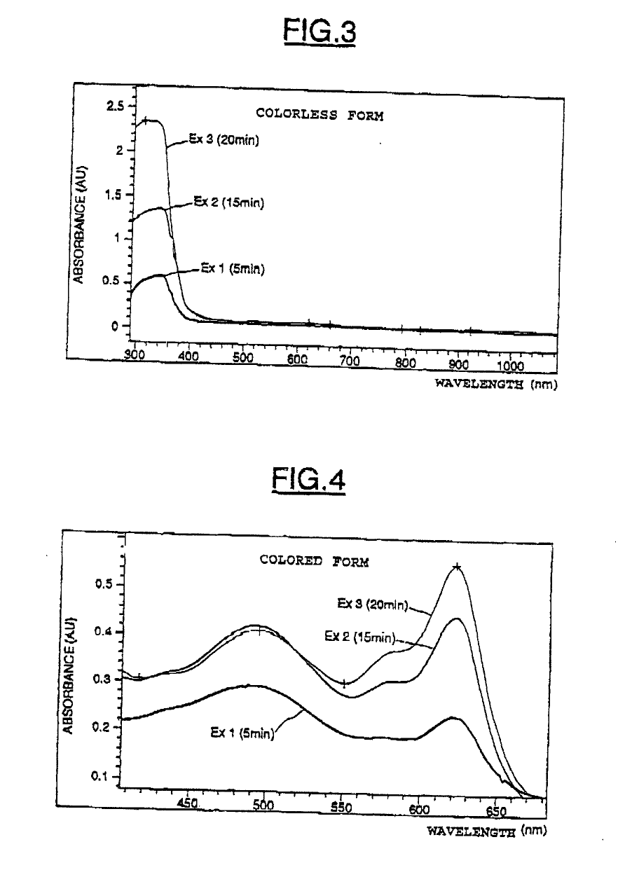

The incorporation of the additives was carried out in the laboratory device represented diagrammatically in FIGS. 1 and 2.

The device represented in FIG. 1 comprises a CO₂ source connected to a pump 2 which is itself connected to a high-pressure tubular reactor 3 placed in an oven 4.

Valves make it possible to isolate the CO₂ source from the pump 2 and the reactor 3.

As it seen in FIG. 2, the reactor 3 comprises a tubular body 5, the two ends of which are closed by plates made of sintered glass 6 and 7 and stoppers 8 and 9. The stopper 8 is provided with means for introducing CO₂ and is connected to the pump 2. Inside the tubular body 5 of the reactor, a transparent polymer substrate 10 for an ophthalmnic article is placed between two cotton pads 12, 13, while an additive 11 or a mixture of additives intended to be incorporated in the substrate is placed in the reactor, next to the substrate 10, between the cotton pad 13 and a third cotton pad 14.

When operating, CO₂ is introduced from the source 1 into the reactor 3 and brought to the pressure greater than the critical pressure and heated by means of the oven to a desired temperature greater than the critical temperature. The CO₂ is maintained under the chosen supercritical conditions, in the static state, in the reactor 3 for predetermined time necessary for the incorporation of the additive. At the end of the incorporation, the CO₂ is removed from the reactor and from the substrate by returning the pressure and the temperature to ambient pressure and temperature (generally normal pressure and temperature or close to normal) and by allowing the CO₂ to discharge from the substrate under these ambient pressure and temperature conditions. The substrate incorporating the additive is then recovered.

### EXAMPLES 1 TO 3

Three test specimens, with a thickness of 1 mm, of a polymer substrate obtained by polymerization of the following polymerizable composition, described in Patent Application WO 95/10790, were treated in the reactor described above.

| | Parts by weight |
|---|---|
| Base Ingredients | |
| Ethoxybisphenol A dimethacrylate containing 2.5 | 43.5 |
| ethoxy units | |
| Poly(ethylene glycol) with a molecular mass of | 21.0 |
| 600, terminated at both ends by methacrylate | |
| 1,3-Diisopropenylbenzene | 6.0 |
| 2-Phenoxyethyl methacrylate | 20.5 |
| Poly(ethylene glycol) with a molar mass of 200, | 8.7 |
| containing a benzoate ending at both ends | |
| Triphenyl phosphite | 0.3 |
| Diethyl pyrocarbonate | 0.15 |
| Initiator | |
| Diisopropyl peroxydicarbonate | 1.5 |
| OO-tert-Butyl O-2-ethylhexyl mono- | 0.5 |
| pcroxycarbonatc | |

The polymerizable composition is poured into a flat-sheet mold. The mold is placed in a circulating air oven and the composition is cured by using following curing cycle.

| Cumulative hours | Temperature of the oven °C. |
|---|---|
| 0 | 34 |
| 24 | 36 |
| 32 | 44 |
| 34 | 46 |
| 36 | 48 |
| 38 | 50 |
| 40 | 54 |
| 42 | 58 |
| 44 | 64 |
| 46 | 69 |
| 48 | 85 |
| 49 | 105 |
| 49.5 | 130 |
| 50.5 | 130 (end of the cycle) |

The polymerizable is allowed to cool in the oven back to approximately 80° C. and is then withdrawn from the oven and removed from the mold.

The additive to be incorporated was a mixture of photochromic substances comprising 55% by weight of a compound of formula:

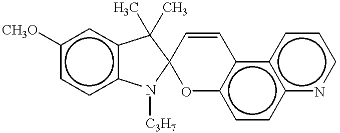

described in Patent Application WO 90/12819 (“blue” dye), and 45% by weight of a compound of formula:

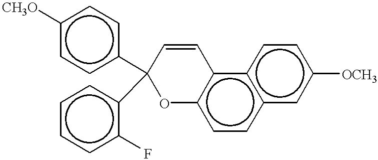

described in Patent Application WO 90/17071 (“orange” dye).

100 mg of the above mixture was placed in the reactor.

The operating conditions for the supercritical CO₂ were as follows:

P=20 MPa

T=80° C.

Density ρ_{CO}_{₂}=0.6 g/cm³.

Each of the test specimens of Examples 1 to 3 was subjected to a different treatment time, namely 5, 15 and 20 minutes respectively.

The test specimens obtained are virtually colored to the core.

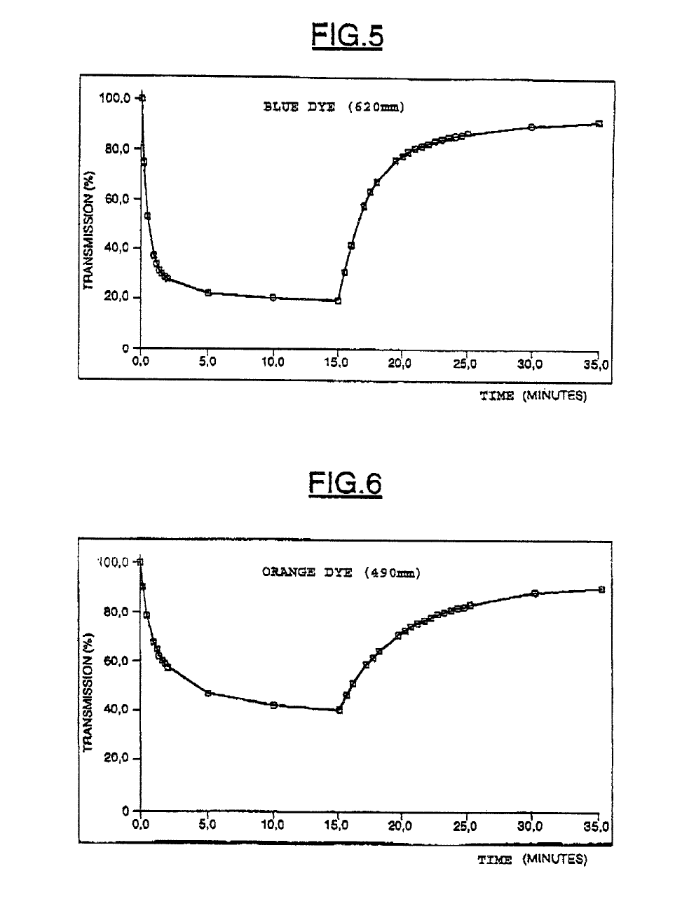

The degree of impregnation of the photochromic substances into the substrate was monitored by UV spectroscopy. The results are represented in FIGS. 3 and 4, which respectively represent the absorption curves of the colorless form and of the colored form of the test specimens of Examples 1 to 3.

The test specimens were irradiated with a Xenon lamp, 0.9 mW/cm² (UV), 73 klux (visible), for 15 minutes (coloring phase).

Irradiation is then stopped. A decoloring phase takes place.

The variation in the percentage of transmission of the test specimen during the two phases is measured by being placed at the wavelength λₘₐₓ corresponding to the maximum absorption of each of the photochromic substances.

The kinetic study of the photochromic substances was carried out at 23° C. at the wavelength corresponding to the absorption maximum of each of the substances.

The results are shown in Tables I and II and in FIGS. 5 and 6.

TABLE I
(“Blue” dye)

| Time in minutes | Time in seconds | % of transmission | Absorbance |
|---|---|---|---|
| 0.0 | 0 | 100.1 | 0.000 |
| 0.2 | 12 | 74.7 | 0.127 |
| 0.5 | 30 | 52.8 | 0.277 |
| 1.0 | 60 | 37.1 | 0.430 |
| 1.2 | 72 | 33.9 | 0.470 |
| 1.4 | 84 | 31.5 | 0.502 |
| 1.6 | 96 | 29.8 | 0.525 |
| 1.8 | 108 | 28.5 | 0.545 |
| 2.0 | 120 | 27.5 | 0.560 |
| 5.0 | 300 | 22.1 | 0.657 |
| 10.0 | 600 | 20.2 | 0.694 |
| 15.0 | 900 | 19.5 | 0.709 |
| 15.5 | 930 | 31.2 | 0.505 |
| 16.0 | 960 | 41.9 | 0.377 |
| 17.0 | 1020 | 57.9 | 0.237 |
| 17.5 | 1050 | 63.4 | 0.198 |
| 18.0 | 1080 | 67.8 | 0.169 |
| 19.5 | 1170 | 76.1 | 0.118 |
| 20.0 | 1200 | 77.9 | 0.108 |
| 20.5 | 1230 | 79.5 | 0.100 |
| 21.0 | 1260 | 80.8 | 0.093 |
| 21.5 | 1290 | 81.9 | 0.87 |
| 22.0 | 1320 | 82.9 | 0.081 |
| 22.5 | 1350 | 83.1 | 0.077 |
| 23.0 | 1380 | 84.6 | 0.073 |
| 23.5 | 1410 | 85.2 | 0.070 |
| 24.0 | 1440 | 85.8 | 0.066 |
| 24.5 | 1470 | 86.4 | 0.063 |
| 25.0 | 1500 | 86.9 | 0.061 |
| 30.0 | 1800 | 90.5 | 0 043 |
| 35.0 | 2100 | 92.5 | 0.034 |
| Coloration T1/2 | Sec. | 45.2 | |
| Decolaration T1/2 | Sec. | 69.9 | |

measurement at 23° C., 0.9 mW/cm², 73 klux at λ = 620 nm.

TABLE II
(“Orange” dye)

| Time in minutes | Time in seconds | % of transmission | Absorbance |
|---|---|---|---|
| 0.0 | 0 | 100.1 | 0.001 |
| 0.2 | 12 | 89.5 | 0.048 |
| 0.5 | 30 | 78.0 | 0.108 |
| 1.0 | 60 | 67.1 | 0.173 |
| 1.2 | 72 | 64.2 | 0.193 |
| 1.4 | 84 | 61.9 | 0.208 |
| 1.6 | 96 | 59.9 | 0.223 |
| 1.8 | 108 | 58.1 | 0.236 |
| 2.0 | 120 | 56.8 | 0.246 |
| 5.0 | 300 | 46.2 | 0.335 |
| 10.0 | 600 | 41.7 | 0.380 |
| 15.0 | 900 | 40.1 | 0.396 |
| 15.5 | 930 | 46.2 | 0.335 |
| 16.0 | 960 | 50.9 | 0.293 |
| 17.0 | 1020 | 58.4 | 0.234 |
| 17.5 | 1050 | 61.4 | 0.212 |
| 18.0 | 1080 | 64.0 | 0.194 |
| 19.5 | 1170 | 70.5 | 0.152 |
| 20.0 | 1200 | 72.1 | 0.142 |
| 20.5 | 1230 | 73.8 | 0.132 |
| 21.0 | 1260 | 75.2 | 0.124 |
| 21.5 | 1290 | 76.4 | 0.117 |
| 22.0 | 1320 | 77.7 | 0.110 |
| 22.5 | 1350 | 78.8 | 0.104 |
| 23.0 | 1380 | 79.8 | 0.098 |
| 23.5 | 1410 | 80.6 | 0.094 |
| 24.0 | 1440 | 81.4 | 0.089 |
| 24.5 | 1470 | 82.2 | 0.085 |
| 25.0 | 1500 | 82.9 | 0.081 |
| 30.0 | 1800 | 87.5 | 0.058 |
| 35.0 | 2100 | 89.7 | 0.047 |
| Coloration T1/2 | Sec. | 76.1 | |
| Decoloration T1/2 | Sec. | 173.3 | |

measurement at 23° C., 0.9 mW/cm², 73 klux at λ = 490 nm.

### EXAMPLE 4

The same photochromic substances as in Examples 1 to 3 were incorporated in a polycarbonate substrate (thermoplastic Polycarbonate from the Company DALLOZ).

A plasticizer, dioctyl phthalate, was initially incorporated by using the same equipment as above and the following conditions:

P=20 MPa

T=80° C.

Density ρ_{CO}_{₂}=0.6 g/cm³

Duration: 15 minutes.

The photochromic substances are then incorporated in the same way with the following operating conditions:

P=20 MPa

T=80° C.

Duration: 15 minutes.

The amount of plasticizer and of photochromic substances incorporated are determined by weighing. The same amount, approximately 1% by weight, of plasticizer and of photochromic substances was incorporated.

### EXAMPLE 5

The primary dyes shown below are incorporated in a substrate with a refractive index of 1.6, sold by the Company ESSILOR under the name ORMIL® (material regarded as exhibiting serious difficulties in coloring), by using the equipment described above and the following reaction conditions for the supercritical CO₂:

P=40 MPa

T=120° C.

Density ρ_{CO}_{₂}=0.75 g/cm³

The duration of treatment is 10 minutes. An intense coloring of the material is obtained.

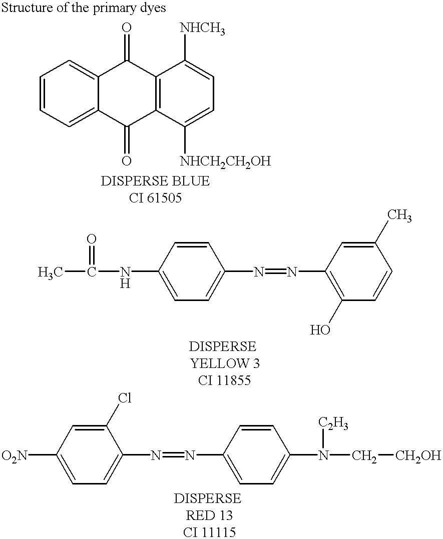

### EXAMPLE 6

Test specimens comprising a substrate composed of the material sold by the Company ESSILOR under the name ORMA® (diethylene glycol bis(allyl carbonate) polymer) provided with an abrasion-resistant coating with a thickness of 3 μm (varnish described in Example 3 of the document EP-A-0.614.957), a coating which is virtually impossible to color, are subjected to a treatment for incorporation of the dye “Disperse Red 13”, as in the preceding examples, with the following conditions for the supercritical CO₂:

P=40 MPa

T=120° C.

Density ρ_{CO}_{₂}=0.75 g/cm³

The duration of treatment is 10 minutes. A coloring of the test specimen is obtained.

### EXAMPLE 7

Contact lenses made of poly(methyl methacrylate) (PMMA), with a thickness of 160 μm, were treated as described above in order to incorporate the dye “Disperse Red 13” therein. The optical parameters of the lenses, the supercritical CO₂ and treatment conditions, and the results are shown in Table III below.

TABLE III

| | | | | Superencital CO₂ | | | | | |
|---|---|---|---|---|---|---|---|---|---|
| | Optical parameter of the lens | | | T | P | p | Duration of the | | |
| Example | Power | Ωr | Diameter Ø | (° C.) | (MPa) | (g/cm³) | treatment (nm) | Coloring | Observations |
| 7 | −175 | 770 | 8.50 | 60 | 85 | 0.217 | 10 | Red | Undeformed |
| | | | | | | | | transmission | appearance of a |
| | | | | | | | | Tv = 90% | cylinder |

1. Method for incorporating at least one photochromic additive in a finished or semi-finished ophthalmic article comprising a transparent polymer substrate containing at least one free plasticizer, which comprises:
introducing a supercritical fluid into a reactor containing the ophthalmic article and the photochromic additive to be incorporated;
maintaining the supercritical fluid in the reactor, in a static state, for a predetermined period of time, in order to obtain the incorporation of the photochromic additive in the polymer substrate of the ophthalmic article to a predetermined depth;
removing the supercritical fluid; and
recovering the ophthalmic article in which the photochromic additive has been incorporated.

2. Method according to claim 1, wherein the polymers of the transparent substrate are selected from the group consisting of allylic polymers, polyol (allyl carbonate) polymers, polyacrylates, poly(alkyl acrylate)s, vinyl polymers, polyurethanes, polythiourethanes and polycarbonates.

3. Method according to claim 1, wherein the temperature of the supercritical fluid is lower by at least 30° C. than the glass transition temperature, under normal conditions, of the polymer or polymers of the substrate.

4. Method according to claim 3, wherein the temperature of the supercritical fluid is lower by 50° C. than the glass transition temperature, under normal conditions, of the polymer or polymers of the substrate.

5. Method according to claim 1, wherein the duration of maintenance of the supercritical fluid in the reactor is between 1 and 30 minutes.

6. Method according to claim 1, wherein the duration of maintenance of the supercritical fluid in the reactor is from 5 to 20 minutes.

7. Method according to claim 1, wherein the supercritical fluid is carbon dioxide.

8. Method according to claim 1, wherein the plasticizer is selected from the group consisting of linear or branched phthalates, C₁₈-C₃₀ fatty acid esters and poly(ethylene glycol)dibenzoates.

9. Method according to claim 1, wherein the ophthalmic article is a spectacle lens.

10. Method according to claim 1, wherein the ophthalmic article is a contact lens.

11. Method for the photochromization of a finished or semi-finished ophthalmic article comprising a transparent polymer substrate containing a free plasticizer which comprises:
A. A first stage comprising:
the insertion into a reactor of a transparent polymer substrate and of a plasticizer for the substrate,
the introduction into the reactor of a supercritical fluid,
the maintenance of the supercritical fluid in the reactor, in a static state, for a predetermined period of time, in order to obtain the incorporation of the plasticizer in the polymer substrate, and
the removal of the supercritical fluid; and
B. A second stage comprising:
the insertion into the reactor containing the plasticized polymer substrate of one or more photochromic compounds;
the introduction of a supercritical fluid,
the maintenance of the supercritical fluid in the reactor, in a static state, for a predetermined period of time, in order to obtain the incorporation of the photochromic compound or compounds in the plasticized polymer substrate of the ophthalmic article to a predetermined depth,
the removal of the supercritical fluid, and
the recovery of the ophthalmic article in which the photochromic compound or compounds are incorporated.

12. Method according to claim 11, wherein the polymers of the transparent substrate are selected from the group consisting of allylic polymers, polyol (allyl carbonate) polymers, polyacrylates, poly(alkyl acrylate)s, vinyl polymers, polyurethanes, polythiourethanes and polycarbonates.

13. Method according to claim 11, wherein the temperature of the supercritical fluid is lower by at least 30° C. than the glass transition temperature, under normal conditions, of the polymer or polymers of the substrate.

14. Method according to claim 13, wherein the temperature of the supercritical fluid is lower by 50° C. than the glass transition temperature, under normal conditions, of the polymer or polymers of the substrate.

15. Method according to claim 11, wherein the duration of maintenance of the supercritical fluid in the reactor is between 1 and 30 minutes.

16. Method according to claim 11, wherein the duration of maintenance of the supercritical fluid in the reactor is from 5 to 20 minutes.

17. Method according to claim 11, wherein the supercritical fluid is carbon dioxide.

18. Method according to claim 11, wherein the plasticizer is selected from the group consisting of linear or branched phthalates, C₁₈-C₃₀ fatty acid esters and poly(ethylene glycol)dibenzoates.

19. Method according to claim 11, wherein the ophthalmic article is a spectacle lens.

20. Method according to claim 11, wherein the ophthalmic article is a contact lens.
